(19) United States
(12) Patent Application Publication
(10) Pub. No.: US 2012/0293928 A1
(43) Pub. Date: Nov. 22, 2012

(54) Backlight Module of Liquid Crystal Display and Back-Plate Film Component

(75) Inventor: Quan Li, Shenzhen City (CN)

(73) Assignee: SHENZHEN CHINA STAR OPTOELECTRONICS TECHNOLOGMINGY Co., LTD., Shenzhen City (CN)

(21) Appl. No.: 13/260,313

(22) PCT Filed: May 27, 2011
(86) PCT No.: PCT/CN2011/074769

§ 371 Date: Sep. 25, 2011

(30) Foreign Application Priority Data
May 17, 2011 (CN) 201120157446.7

(51) Int. Cl. H05K 7/00

(52) U.S. Cl. 361/679.01

(57) ABSTRACT

The present invention discloses a backlight module of a liquid crystal display which comprises an optical film and a back-plate frame. The optical film is disposed on the back-plate frame. The optical film has at least one through hole disposed on its edge. The back-plate frame has at least one positioning structure. The through hole is snapped together with the positioning structure. The present invention also discloses a back-plate film component with better positioning efficiency. This structure is easy to assemble and can also limit the optical film to move in the direction of Z axis thereof, therefore the positioning effect is enhanced. The present invention does not need adhering of tapes, so that the reliability of the overall structure is enhanced, the assembly time and costs are reduced, and it is convenient to rework.

### BACKGROUND OF THE INVENTION

1. Field of Invention

The present invention relates to a backlight module of a liquid crystal display and also relates to a back-plate film component.

2. Related Art

In order to enhance the backlight uniformity and the brightness of the center of the backlight module of liquid crystal display, various optical films are generally applied. The substrates for optical films are mostly smooth PET or PC material. The optical films frequently bounce off due to the insignificant friction coefficient therebetween. The most common method to tackle the problem is to frame the optical films by plastic. But, the gap in the direction of Z axis is generally large due to the consideration of expansion and contraction of plastic materials and PET materials during design. Besides, the design of narrow frames also shrinks the size of the plastic framed optical film sheets. Therefore, the positioning efficiency of the foregoing method is not ideal. Another method is to adhere with tapes, but most of the tapes lose their effectiveness under high temperature and high humidity. Furthermore, tape adhering requires precision and labor costs are relatively high, and it is not convenient to rework.

### SUMMARY OF THE INVENTION

The present invention aims to provide a backlight module of a liquid crystal display (LCD) and a back-plate film component to solve the problem that the positioning efficiency of optical films of the back-plate film component in the backlight module of LCD is not ideal.

The object of the present invention is realized by the following technical solution:

A backlight module of a liquid crystal display (LCD) comprises an optical film and a back-plate frame. The optical film is disposed on the back-plate frame. The optical film having at least one through hole disposed on its edge. The through hole includes a wide portion and a narrow portion. The back-plate frame has at least one positioning structure which is a protrusion element. The cross section of the protrusion element is in an upside-down L-shape. The optical film is inserted by the positioning structure of the back-plate frame from the wide portion of the through hole, and then the optical film is moved horizontally to shift the positioning structure into the narrow portion. An upper portion of the protrusion element is snapped on a rear side of the optical film. A gap between the through hole and the protrusion element is 0.15-0.5 mm. The protrusion element is a bent wall formed by punching and bending the upper portion. The optical film is one or more types of diffusion plate, diffusion sheet and brightness enhancement film. The through hole is in L-shape or b-shape.

A backlight module of a liquid crystal display comprises an optical film and a back-plate frame. The optical film is disposed on the back-plate frame. The optical film has at least one through hole disposed on its edge. The back-plate frame has at least one positioning structure which is a protrusion element. The through hole and the positioning structure are snapped together.

In one of the embodiments of the present invention, the through hole includes a wide portion and a narrow portion. The positioning structure is a protrusion element with an upside-down L-shaped cross section. The optical film is inserted by the positioning structure of the back-plate frame from the wide portion of the through hole, and then the optical film is moved horizontally to shift the positioning structure into the narrow portion. The upper portion of the protrusion element is snapped on the rear side of the optical film.

In one of the embodiments of the present invention, an upper portion of the through hole is the narrow portion, while a lower portion of the through hole is the wide portion. Both of the wide portion and the narrow portion are rectangular. The width of the wide portion is larger than that of the narrow portion.

In one of the embodiments of the present invention, an upper portion of the through hole is the narrow portion, while a lower portion of the through hole is the wide portion. The narrow portion is the combination of a first rectangle and a first semi-circle. The first semi-circle is disposed on top of the first rectangle. The wide portion is the combination of a second rectangle and a second semi-circle. The second semi-circle is disposed on one side of the second rectangle.

In one of the embodiments of the present invention, an upper portion of the through hole is the narrow portion, while a lower portion of the through hole is the wide portion. The narrow portion is a first rectangle. The wide portion is the combination of a second rectangle and a second semi-circle. The second semi-circle is disposed on one side of the second rectangle.

In one of the embodiments of the present invention, a gap between the through hole and the positioning structure is 0.15-0.5 mm.

In one of the embodiments of the present invention, the protrusion element is a bent wall formed by punching and bending its upper portion.

In one of the embodiments of the present invention, the optical film is one or more types of diffusion plate, diffusion sheet and brightness enhancement film.

The present invention also provides a back-plate film component, and the technical solution thereof is that: a back-plate film component comprises an optical film and a back-plate frame. The optical film is disposed on the back-plate frame. The optical film has at least one through hole disposed on its edge. The back-plate frame has at least one positioning structure. The through hole and the positioning structure are snapped together.

In the backlight module of the liquid crystal display and the back-plate film component of the present invention, the through hole of the optical film is snapped together with positioning structure of the back-plate frame. The structure is easy to assemble and the optical film is limited to move in the direction of Z axis thereof. Therefore, the positioning efficiency is enhanced. More specifically, the upper portion of the protrusion element of the positioning structure is snapped on the rear side of the optical film, and thus the optical film is limited to move in the direction of Z axis. The present invention does not need adhering of tapes, so that the reliability of the overall structure is enhanced, the assembly time and costs are reduced, and it is convenient to rework.

### BRIEF DESCRIPTION OF THE DRAWINGS

FIG. 1 is an assembly illustration of an optical film of a backlight module of a liquid crystal display;

FIG. 2 is an illustration of a positioning structure of a back-plate frame of a backlight module of a liquid crystal display;

FIG. 3 is an illustration of a through hole of an optical film of a first embodiment of a backlight module of a liquid crystal display;

FIG. 4 is an illustration of a through hole of an optical film of a second embodiment of a backlight module of a liquid crystal display; and

FIG. 5 is an illustration of a through hole of an optical film of a third embodiment of a backlight module of a liquid crystal display.

### DETAILED DESCRIPTION OF THE INVENTION

The structure and the technical means adopted by the present invention to achieve the above and other objects can be best understood by referring to the following detailed description of the preferred embodiments and the accompanying drawings.

### First Embodiment

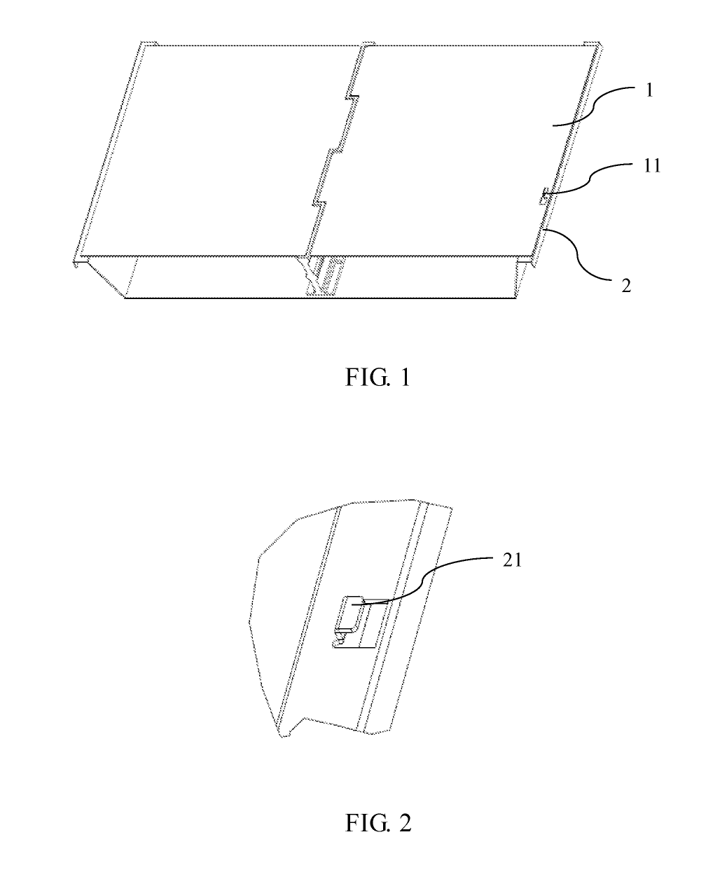

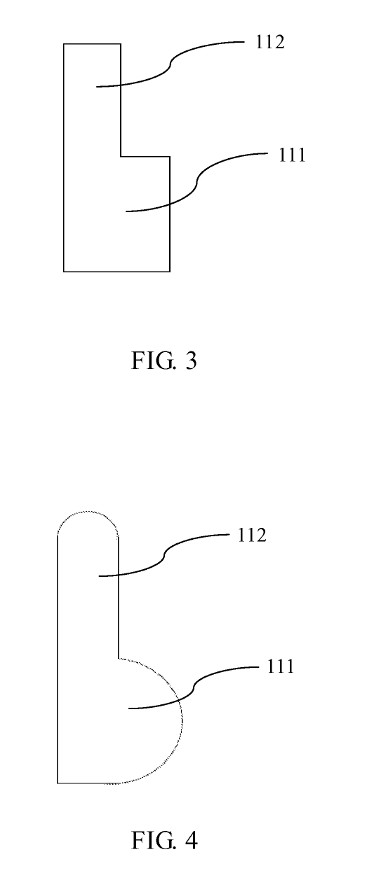

Referring to FIGS. 1 and 2, a backlight module of a liquid crystal display is illustrated, and comprises a light source, an optical film 1, a back-plate frame 2, a diffusion plate, a light guide plate and a bottom reflection sheet. The optical film 1 is disposed on top of the back-plate frame 2. The optical film 1 has at least one through hole 11 disposed on its edge. FIG. 3 shows the through hole 11 which comprises a wide portion 111 and a narrow portion 112. The lower portion of the through hole 11 is the wide portion 111, while the upper portion of the through hole 11 is the narrow portion 112. Both of the wide portion 111 and the narrow portion 112 are rectangular. The width of the wide portion 111 is larger than that of the narrow portion 112.

As shown in FIGS. 1 and 2, the back-plate frame 2 has at least one positioning structure 21 which is a protrusion element. The cross section of the protrusion element is in an upside-down L-shape. The positioning structure 21 and the through hole 11 are corresponding to each other. The optical film 1 is inserted by the positioning structure 21 of the back-plate frame 2 from the wide portion 111 of the through hole 11, and then the optical film 1 is moved horizontally to shift the positioning structure 21 into the narrow portion 112. The upper portion of the protrusion element is snapped on the rear side of the optical film 1. Therefore, the optical film 1 is limited to move in the direction of Z axis thereof by the upper portion of the protrusion element. In this embodiment, the protrusion element is a bent wall formed by punching and bending the upper portion.

A gap between the through hole 11 and the positioning structure 21 is set to be 0.15-0.5 mm. There can be two or a plurality of the through hole 11 of the optical film 1 and the positioning structure 21 of the back-plate frame 2, disposed corresponding to each other. The optical film 1 is one or more types of diffusion plate, diffusion sheet and brightness enhancement film. The backlight module of liquid crystal display employs LED (light-emitting diode) or CCFL (cold cathode fluorescent lamp) as its light source.

### Second Embodiment

Referring to FIG. 4, the differences between the first and the second embodiments is that the upper portion of the through hole 11 is the narrow portion 112, while the lower portion of the through hole 11 is the wide portion 111. The narrow portion 112 is the combination of a first rectangle and a first semi-circle. The first semi-circle is disposed on top of the first rectangle. The wide portion 112 is the combination of a second rectangle and a second semi-circle. The second semi-circle is disposed on one side of the second rectangle.

### Third Embodiment

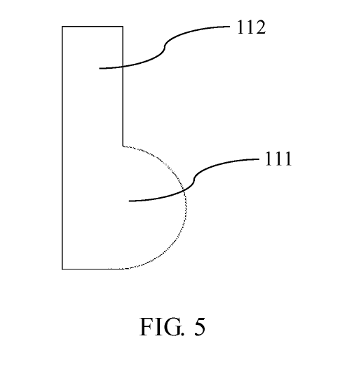

Referring to FIG. 5, the differences between the first and the third embodiments is that the upper portion of the through hole 11 is the narrow portion 112, while the lower portion of the through hole 11 is the wide portion 111. The narrow portion 112 is a first rectangle. The wide portion 111 is the combination of a second rectangle and a second semi-circle. The second semi-circle is disposed on one side of the second rectangle.

The present invention does not limit the quantity and the disposing positions of the through hole 11 and the positioning structure 21. Furthermore, the contact between the positioning structure 21 of the back-plate frame 2 and the optical film 1 can not be defective such as having burrs, etc.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A backlight module of a liquid crystal display, comprising an optical film and a back-plate frame, wherein said optical film is disposed on said back-plate frame, said optical film has at least one through hole disposed on its edge, said through hole includes a wide portion and a narrow portion, said back-plate frame has at least one positioning structure which is a protrusion element, the cross section of said protrusion element is in an upside-down L-shape, said optical film is inserted by said positioning structure of said back-plate frame from said wide portion of said through hole, and then said optical film is moved horizontally to shift said positioning structure into said narrow portion, an upper portion of said protrusion element is snapped on a rear side of said optical film, a gap between said through hole and said protrusion element is 0.15-0.5 mm, said protrusion element is a bent wall formed by punching and bending the upper portion thereof, said optical film is one or more type of a diffusion plate, a diffusion sheet and a brightness enhancement film, and said through hole is in L-shape or b-shape.

2. A backlight module of a liquid crystal display, comprising an optical film and a back-plate frame, wherein said optical film is disposed on said back-plate frame, said optical film has at least one through hole disposed on its edge, said back-plate frame has at least one positioning structure, and said through hole is snapped together with said positioning structure.

3. The backlight module of the liquid crystal display as claimed in claim 2, wherein said through hole includes a wide portion and a narrow portion, said positioning structure is a protrusion element, the cross section of said protrusion element is in an upside-down L-shape, said optical film is inserted by said positioning structure of said back-plate frame from said wide portion of said through hole, then said optical film is moved horizontally to shift said positioning structure into said narrow portion, and an upper portion of said protrusion element is snapped on a rear side of said optical film.

4. The backlight module of the liquid crystal display as claimed in claim 3, wherein the upper portion of said through hole is said narrow portion, while a lower portion of said through hole is said wide portion, both of said wide portion and said narrow portion are rectangular, and the width of said wide portion is larger than that of said narrow portion.

5. The backlight module of the liquid crystal display as claimed in claim 3, wherein the upper portion of said through hole is said narrow portion, while a lower portion of said through hole is said wide portion, said narrow portion is the combination of a first rectangle and a first semi-circle, said first semi-circle is disposed on top of said first rectangle, said wide portion is the combination of a second rectangle and a second semi-circle, and said second semi-circle is disposed on one side of said second rectangle.

6. The backlight module of the liquid crystal display as claimed in claim 3, wherein the upper portion of said through hole is said narrow portion, while a lower portion of said through hole is said wide portion, said narrow portion is a first rectangle, said wide portion is the combination of a second rectangle and a second semi-circle, and said second semi-circle is disposed on one side of said second rectangle.

7. The backlight module of the liquid crystal display as claimed in claim 2, wherein a gap between said through hole and said positioning structure is 0.15-0.5 mm.

8. The backlight module of the liquid crystal display as claimed in claim 2, wherein said protrusion element is a bent wall formed by punching and bending the upper portion thereof

9. The backlight module of the liquid crystal display as claimed in claim 2, wherein said optical film is one or more type of a diffusion plate, a diffusion sheet and a brightness enhancement film.

10. A back-plate film component, comprising an optical film and a back-plate frame, wherein said optical film is disposed on said back-plate frame, said optical film has at least one through hole disposed on its edge, said back-plate frame has at least one positioning structure, and said through hole is snapped together with said positioning structure.

11. The back-plate film component as claimed in claim 10, wherein said through hole includes a wide portion and a narrow portion, said positioning structure is a protrusion element, the cross section of said protrusion element is in an upside-down L-shape, said optical film is inserted by said positioning structure of said back-plate frame from said wide portion of said through hole, then said optical film is moved horizontally to shift said positioning structure into said narrow portion, and an upper portion of said protrusion element is snapped on a rear side of said optical film.

12. The back-plate film component as claimed in claim 11, wherein the upper portion of said through hole is said narrow portion, while a lower portion of said through hole is said wide portion, both of said wide portion and said narrow portion are rectangular, and the width of said wide portion is larger than that of said narrow portion.

13. The back-plate film component as claimed in claim 11, wherein the upper portion of said through hole is said narrow portion, while a lower portion of said through hole is said wide portion, said narrow portion is the combination of a first rectangle and a first semi-circle, said first semi-circle is disposed on top of said first rectangle, said wide portion is the combination of a second rectangle and a second semi-circle, and said second semi-circle is disposed on one side of said second rectangle.

14. The back-plate film component as claimed in claim 11, wherein the upper portion of said through hole is said narrow portion, while a lower portion of said through hole is said wide portion, said narrow portion is a first rectangle, said wide portion is the combination of a second rectangle and a second semi-circle, said second semi-circle is disposed on one side of said second rectangle.

15. The back-plate film component as claimed in claim 10, wherein said protrusion element is a bent wall formed by punching and bending the upper portion thereof.
